(19) United States
(12) Patent Application Publication
(10) Pub. No.: US 2026/0182280 A1
(43) Pub. Date: Jun. 25, 2026

(54) ETCHING METHOD FOR SUBSTRATE AND SEMICONDUCTOR DEVICE THEREOF

(71) Applicant: ADVANCED MICRO-FABRICATION EQUIPMENT INC. CHINA, Shanghai (CN)

(72) Inventors: Kai ZHANG, Shanghai (CN); Weina XU, Shanghai (CN); Jianqiu HOU, Shanghai (CN); Ziyang WU, Shanghai (CN); Yichuan ZHANG, Shanghai (CN)

(21) Appl. No.: 19/113,851

(22) PCT Filed: Aug. 30, 2023
(86) PCT No.: PCT/CN2023/115816

§ 371 Date: Jan. 5, 2026

(30) Foreign Application Priority Data
Sep. 29, 2022 (CN) 202211197076.9

(51) Int. Cl. H10P 50/28; H10P 14/60; H10P 50/00; H10W 74/01

(52) U.S. Cl. CPC H10P 50/283; H10P 14/6339; H10W 74/01; H10P 50/73

(57) ABSTRACT

Disclosed are an etching method for a substrate and a semiconductor device thereof, the method including: transferring a substrate into a treatment chamber; and introducing an etching gas and a passivating gas into the treatment chamber, the etching gas including one or more fluorinated gases containing carbon so as to perform etching to form a recessed structure on the substrate, the passivating gas including a first passivating gas and a second passivating gas and being used for forming an etching protection area on a side wall of the recessed structure, the first passivating gas including a halogen element and/or a hydrogen halide gas, and the second passivating gas including a gasified heavy metal dopant. During treatment, the total gas amount of the second passivating gas is less than the total gas amount of the first passivating gas.

### CROSS-REFERENCE TO RELATED APPLICATIONS

This application is a national stage of International Application No. PCT/CN2023/115816, filed on Aug. 30, 2023, which claims priority to and the benefit of Chinese Patent Application No. 202211197076.9, filed on Sep. 29, 2022. Both of the aforementioned applications are hereby incorporated by reference in their entireties.

### TECHNICAL FIELD

The present disclosure pertains to the technical field of semiconductors, in particular to an etching method for a substrate and a semiconductor device thereof.

### BACKGROUND

With the flourishing development of the semiconductor technology and the increasing improvement of the integration degree of devices, the dimension of a chip is smaller, and in order to ensure the quality of the chip, the technological requirements for the semiconductors are becoming more and stricter. Dimension reduction is one of the development driving forces for integrated circuit handling, and by reducing the dimension, synchronous improvement of the cost effectiveness and device performance can be achieved.

In terms of a memory device, in order to reduce the dimension and explore a next generation memory device, a 3D NAND flash memory cell is proposed. The 3D NAND is formed by stacking multiple layers. With the increase of the integration degree of a device, the number of stacked layers of the 3D NAND also increases, and the depth of a recessed structure serving as a feature area of a word line and a contact is also increasing. At present, the number of stacked layers of the 3D NAND generally 128, and a recessed structure corresponding thereto has a high aspect ratio (HAR). A recessed structure designed with a high aspect ratio can break through a capacity limit on a plane, but also greatly increases difficulty in etching the recessed structure, which brings a great challenge in terms of processes and devices.

Currently, in a mainstream etching method for a recessed structure, a process gas with a strong polymerization capability is mostly used to perform protection treatment on a substrate in a capacitive coupling plasma etching apparatus, which can well protect a mask and a side wall of the recessed structure, and prevent a critical dimension (CD) of the recessed structure from being excessively expanded. However, when the aspect ratio of the recessed structure is higher than 50, due to the accumulation effect, the process gas or the polymer by-products generated thereby are likely to be aggregated, resulting in the closing of the mask or blocking of the recessed structure. In order to perform anisotropic etching, a relatively high bias power needs to be applied, such that the loss of the whole process is increased, and it is difficult to ensure an etching effect inside the recessed structure, and a problem of unevenness still exists inside the recessed structure. It is well known that for a normal substrate, the process from a silicon wafer to the end packaging requires thousands of process flows, and multiple process flows create the unavoidable complexity during treatment. A recessed structure etched on a substrate is the basis of multiple process flows, and the etching quality of the recessed structure is critical to the quality of a subsequent self-aligned multi-pattern device. However, the existing etching method for a recessed structure cannot ensure the manufacturing effect, and may cause problems such as an uneven inner wall of the recessed structure or premature closing, thereby causing the defects of the multi-pattern device, reducing the production rate of the product, and affecting the yield and the production scale of the integrated circuit.

### SUMMARY

The object of the present disclosure is to provide an etching method for a substrate and a semiconductor device thereof, the method including the following operations: transferring a substrate into a treatment chamber; introducing an etching gas and a passivating gas into the treatment chamber to perform treatment on the substrate, the etching gas including one or more fluorinated gases containing carbon so as to perform etching to form a recessed structure on the substrate, the passivating gas including a first passivating gas and a second passivating gas and being used for forming an etching protection area on a side wall of the recessed structure, the first passivating gas including a halogen element and/or a hydrogen halide gas, and the second passivating gas including a gasified heavy metal dopant. During treatment of the passivating gas, in the treatment chamber, the total gas amount of the second passivating gas is less than the total gas amount of the first passivating gas. In the method, the fluorinated gas containing carbon is used as an etching gas, and effective fast etching on a substrate can be implemented by means of free radicals containing fluorine, and an etching protection area is formed on a side wall of the recessed structure by means of cooperation of free radicals containing carbon and a halogen element and/or a hydrogen halide gas and a heavy metal dopant, so as to avoid differential expansion of the side wall of the recessed structure when the substrate is etched by the etching gas, thereby further ensuring the flatness of the side wall of the recessed structure, providing a good basis for the subsequent substrate fabrication, and helping to improve the yield of substrate fabrication. In addition, in the method, the total gas amount of the second passivating gas is further controlled to be less than the total gas amount of the first passivating gas, so as to protect the side wall without blocking a deep hole finally due to its own accumulation, thereby further ensuring the normal progress of treatment the recessed structure.

In order to achieve the object above, the present disclosure is implemented by the following technical solution:
an etching method for a substrate, including the following operations:
transferring a substrate into a treatment chamber;
and introducing an etching gas and a passivating gas into the treatment chamber to perform treatment on the substrate, the etching gas including one or more fluorinated gases containing carbon, so as to perform etching to form a recessed structure on the substrate.

The passivating gas includes a first passivating gas and a second passivating gas, and is used for forming an etching protection area on a side wall of the recessed structure, the first passivating gas includes a halogen element and/or a hydrogen halide gas, and the second passivating gas includes a gasified heavy metal dopant.

During treatment of the passivating gas, the total gas amount of the second passivating gas is smaller than that of the first passivating gas in the treatment chamber.

In one embodiment, the first passivating gas includes one or more of HBr, HI, Br₂ and I₂.

In one embodiment, the gasified heavy metal dopant includes one or more of WF₆, WOF₂Cl₂, WOCl₄, WOF₄, WO₂F₂, WO₂Cl₂, MoF₆, MoCl₂F₂, SnH₄, ReF₆, PbH₄, Ni(CO)₄, GeH₄, GeF₄, AsH₃, AsCl₃, SbB₃, SbCl₃, SeF₆, Se₂Cl₂, TiCl₄ and TaF₅.

In one embodiment, the etching gas includes one or more of CₓF_{y} and CₓH_{y}F_{z}, where x is greater than or equal to 1, y is greater than or equal to 1, z is greater than or equal to 1, and x, y, and z are all positive integers.

In one embodiment, during the treatment, the etching gas is continuously introduced;
and/or the passivating gas is introduced in a pulsed manner.

In one embodiment, the passivating gas is introduced in pulses, and a pulse phase difference between the first passivating gas and the second passivating gas is within 0-1 periods.

In one embodiment, the pulse frequency of the first passivating gas is greater than the pulse frequency of the second passivating gas;
and/or the duration of single-pulsed introduction of the first passivating gas is longer than the duration of single-pulsed introduction of the second passivating gas;
and/or the pulse intensity of the first passivating gas is higher than the pulse intensity of the second passivating gas per unit time.

In one embodiment, the pulse duty cycle of the second passivating gas is less than or equal to the pulse duty cycle of the first passivating gas.

In one embodiment, the pulse period of the second passivating gas is n times the pulse period of the first passivating gas, n being a positive integer.

In one embodiment, the pulse amplitude of the second passivating gas is 1-10% of the pulse amplitude of the first passivating gas.

In one embodiment, the etching gas is introduced in pulses, and the unit period thereof includes a low pulse intensity stage and a high pulse intensity stage.

In one embodiment, within a unit time, the start time of the high pulse intensity stage of the etching gas is the same as the pulse start time of the first passivating gas.

In one embodiment, in a period of the second passivating gas:
the total gas amount of the second passivating gas in the treatment chamber is 1-10% of the total gas amount of the first passivating gas;
and/or the total gas amount of the first passivating gas is 1%-10% of the total gas amount of the etching gas;
and/or the total gas amount of the second passivating gas is 0.1-1% of the total gas amount of the etching gas.

In one embodiment, the range of the flow rate of the first passivating gas is 0-500 sccm;
and/or the range of the flow rate of the second passivating gas is 0-30 sccm;
and/or the range of the flow rate of the etching gas is 0-1000 sccm.

In one embodiment, the treatment temperature of the substrate less than or equal to −20° C.

In one embodiment, the treatment temperature of the substrate is −60° C.

In one embodiment, the treatment temperature of the substrate less than or equal to 25° C.

In one embodiment, the aspect ratio of the recessed structure is greater than or equal to 40.

In one embodiment, the aspect ratio of the recessed structure is greater than or equal to 50.

Further, the present disclosure also discloses an etching method for a substrate, including the following operations:
transferring a substrate into a treatment chamber;
introducing an etching gas and a passivating gas into the treatment chamber to perform treatment on the substrate so as to generate a recessed structure, where the treatment temperature of the substrate is less than or equal to −20° C., the etching gas includes a C1 gas containing F for etching the substrate, and the passivating gas includes a first passivating gas HBr and a second passivating gas WF6, so as to form an etch protection area on a sidewall of the recessed structure.

In one embodiment, the aspect ratio of the recessed structure is greater than or equal to 50.

In one embodiment, during the treatment, the etching gas is continuously introduced.

In one embodiment, the passivating gas is introduced in a pulsed manner, where the duty cycle of the HBr gas is twice the duty cycle of the WF6 gas.

Further, the present disclosure also discloses a semiconductor device, including:
a substrate, where
stacked layers of different materials are alternately provided on the substrate, and the stacked layers include silicon nitride layers and silicon oxide layers; and
a recessed structure manufactured by using the etching method for a substrate stated above is provided in the stacked layers.

Compared with the prior art, the present disclosure has the following advantages:

In the etching method for a substrate and a semiconductor device thereof provided by the present disclosure, the method including the following operations: transferring a substrate into a treatment chamber; introducing an etching gas and a passivating gas into the treatment chamber to perform treatment on the substrate, the etching gas including one or more fluorinated gases containing carbon so as to perform etching to form a recessed structure on the substrate, the passivating gas including a first passivating gas and a second passivating gas and being used for forming an etching protection area on a side wall of the recessed structure, the first passivating gas including a halogen element and/or a hydrogen halide gas, and the second passivating gas including a gasified heavy metal dopant. During treatment of the passivating gas, in the treatment chamber, the total gas amount of the second passivating gas is less than the total gas amount of the first passivating gas. In the method, the fluorinated gas containing carbon is used as an etching gas, and effective fast etching on a substrate can be implemented by means of free radicals containing fluorine, and an etching protection area is formed on a side wall of the recessed structure by means of cooperation of free radicals containing carbon and a halogen element and/or a hydrogen halide gas and a heavy metal dopant, so as to avoid differential expansion of the side wall of the recessed structure when the substrate is etched by the etching gas, thereby further ensuring the flatness of the side wall of the recessed structure, providing a good basis for the subsequent substrate fabrication, and helping to improve the yield of substrate fabrication. In addition, in the method, the total gas amount of the second passivating gas is further controlled to be less than the total gas amount of the first passivating gas, so as to protect the side wall without blocking a deep hole finally due to its own accumulation, thereby further ensuring the normal progress of treatment the recessed structure.

### BRIEF DESCRIPTION OF THE DRAWINGS

FIG. 1 is a schematic diagram of a part of a semiconductor device of the present disclosure;

FIG. 2-FIG. 4 are schematic diagrams of different etching conditions of a part of the semiconductor device according to the present disclosure;

FIG. 5 is a schematic diagram of an etching method for a substrate according to the present disclosure;

FIG. 6 is a schematic diagram of the flow rates of an etching gas and a passivating gas; and

FIG. 7-FIG. 11 show combinations of different introduction manners of the first passivating gas and the second passivating gas according to the present disclosure.

### DETAILED DESCRIPTION OF THE EMBODIMENTS

To make the object, technical solutions, and advantages of the embodiments of the present disclosure clearer, the technical solutions of the embodiments of the present disclosure are clearly and completely described in the following with reference to the accompanying drawings in the embodiments of the present disclosure. Apparently, the described embodiments are a part rather than all of the embodiments of the present disclosure. All other embodiments obtained by persons of ordinary skill in the art based on the embodiments of the present disclosure without creative efforts shall belong to the scope of protection of the present disclosure.

It should be noted that, herein, the terms “comprises”, “include”, “have”, or any other variation thereof are intended to cover a non-exclusive inclusion, so that a process, a method, an article, or a terminal device including a series of elements not only include those elements, but also include other elements that are not explicitly listed, or further include elements that are inherent to the process, the method, the article, or the terminal device. If no more restrictions exist, an element defined by the expression “comprise . . . ” or “include” does not exclude that another element exists in the process, method, article, or terminal device that includes the element.

It should be noted that, the accompanying drawings all adopt a very simplified form and all use a non-accurate ratio, and are merely used for conveniently and clearly illustrating the object of the embodiments of the present disclosure.

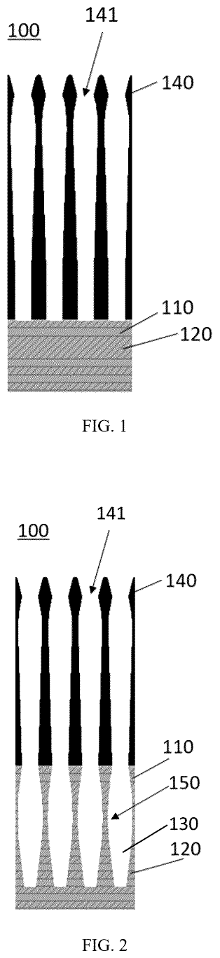

FIG. 1 is a schematic diagram of a part of a semiconductor device of the present disclosure, the semiconductor device includes a substrate 100, the substrate 100 includes stacked layers including different materials and alternately provided thereon, the stacked layers include a first material layer 110 and a second material layer 120, and in the stacked layers, a recessed structure 130 manufactured by using the etching method for a substrate 100 is provided (see FIG. 4). In an etching process, a patterned mask 140 is covered on the stacked layers of the substrate 100, a corresponding target pattern is formed at the position of an opening 141 of the mask 140, and a recessed structure 130 corresponding to the pattern of the mask 140 is finally formed by etching the stack layers, so as to facilitate the subsequent manufacturing of a self-aligned multi-patterned device. In this embodiment, the first material layer 110 and the second material layer 120 are a silicon nitride layer (SiN) and a silicon oxide layer (SiO₂), respectively. Of course, the types of the materials of the first material layer 110 and the second material layer 120 are not limited thereto, and the present disclosure does not limit the types. Exemplarily, in another embodiment, the first material layer 110 and the second material layer 120 are a silicon nitride layer and a polysilicon layer (Si) respectively. Further, the number of stacked layers of the substrate 100 is not limited in the present disclosure, and the more the number of stacked layers is, the higher the integration degree of the device is. In one embodiment, the mask 140 is manufactured of amorphous carbon, and of course, it may be manufactured of other materials, which is not limited in the present disclosure.

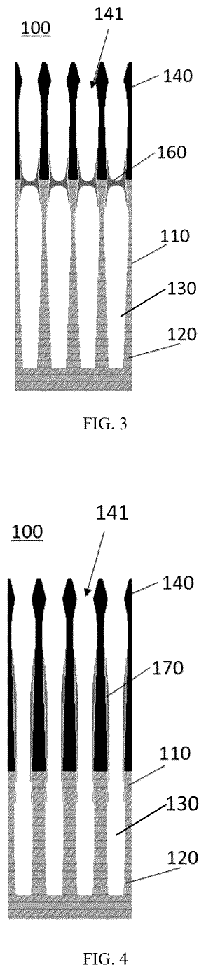

It can be determined from the description above that, the etching quality of the recessed structure 130 is critical to the subsequent manufacturing of a self-aligned multi-patterned device, and along with the development of semiconductor nodes, the requirement on the manufacturing process of the recessed structure 130 with a high aspect ratio is higher. As shown in FIG. 2, when the etching proceeds deeply, the moving trace is changed because the particles in the plasma are reflected by the side wall of the opening 141 of the mask 140 or the side wall of the recessed structure 130, this further results in excessive etching of the side wall of the recessed structure 130 in the stacked layers to form the arched defect 150, the arched defect 150 may cause the stacked layers around it too thin, and when conductive layers are filled in the recessed structure 130, the short circuit or breakdown between adjacent conductive layers is easily created, so the arched defect 150 means that the device is unstable there.

As shown in FIG. 3, for the arched defect 150, a passivating gas may be used to form a protection layer 160 on the side wall of the recessed structure 130; however, in an etching process with a high aspect ratio, the etching time is relatively long, and the protection layer 160 may be deposited on the opening 141 of the mask 140 or the upper portion of the recessed structure 130 to close the opening 141 or the top opening of the recessed structure 130, thereby preventing the etching from proceeding downwards.

On this basis, the present disclosure provides an etching method for a substrate 100. The method can avoid undesired deformation of an inner wall of a recessed structure 130 in an etching process, and can help to generate a normalized recessed structure 130 with a high aspect ratio. It has been verified through experiments that the required collimation can be maintained when the aspect ratio of the recessed structure 130 obtained by using the treatment method for a substrate 100 the present disclosure is greater than or equal to 50. It should be noted that, the method of the present disclosure is not limited to generating the recessed structure 130 with a high aspect ratio, and in the production requirement of a recessed structure 130 with a low aspect ratio, the method may also meet the process requirement.

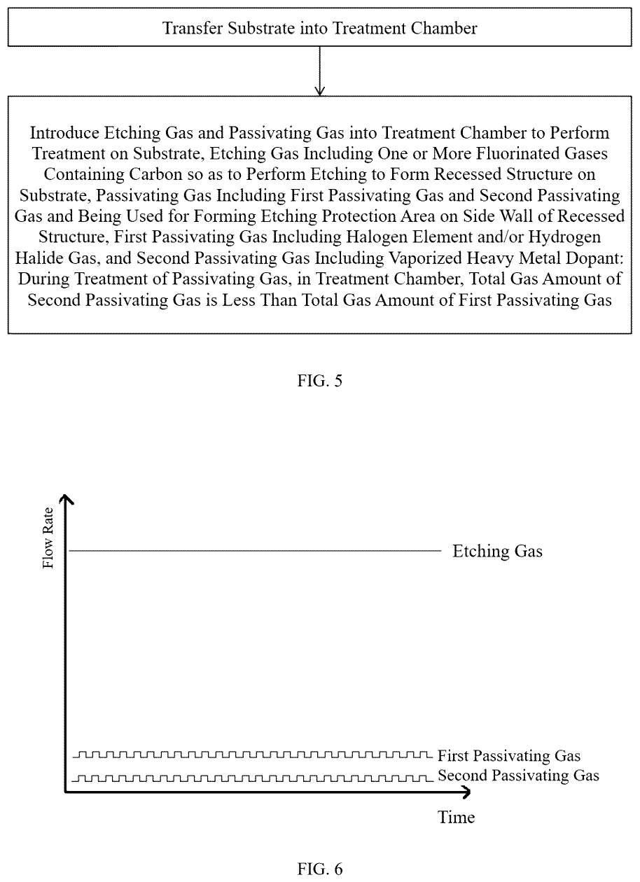

As shown in FIG. 5, the method includes the following operations: transferring a substrate 100 into a treatment chamber; introducing an etching gas and a passivating gas into the treatment chamber to perform treatment on the substrate 100, the etching gas including one or more fluorinated gases containing carbon so as to perform etching to form a recessed structure 130 on the substrate 100, the passivating gas including a first passivating gas and a second passivating gas and being used for forming an etching protection area 170 on a side wall of the recessed structure 130, the first passivating gas including a halogen element and/or a hydrogen halide gas, and the second passivating gas including a gasified heavy metal dopant. During treatment of the passivating gas, in the treatment chamber, the total gas amount of the second passivating gas is less than the total gas amount of the first passivating gas.

In the present disclosure, a fluorinated gas containing carbon is used as a main gas for performing etching to form the recessed structure 130, and a halogen element gas, a hydrogen halide gas or a combination thereof is used as a first passivating gas and a heavy metal dopant gas is used as a second passivating gas, which are used together as a passivating gas combination, so as to achieve a suitable side wall deposition speed and degree for performing etching to form the recessed structure 130. The fluorocarbon radicals/free radicals containing carbon cooperate with the halogen element and/or hydrogen halide gas, and the heavy metal dopant in the side wall protection process, by means of the reaction of carbon-fluorine groups after the first passivating gas and the etching gas are subjected to plasma treatment, a stable protection layer is formed at the opening 141 of the mask 140 and on the side wall of the deep hole formed by the recessed structure 130 of the stacked layer, the second passivating gas dopes the existing side wall protection layer (formed by the first passivating gas) during the side wall protection process to achieve chemical stabilization so as to enhance the chemical stability thereof, in this way, an etching protection area is formed in this area, and the etching protection area can more effectively resist erosion caused by scattered particles during etching, such that it is able to prevent the side wall of the recessed structure 130 from being expanded differently when the etching gas is used to etch the substrate 100. In addition, the flatness of the side wall of the recessed structure 130 is ensured, so as to provide a good foundation for the subsequent machining of the substrate 100, helping to improve the yield of the substrate 100. Further, after being stabilized by the heavy metal dopant, the side wall protection film may always remain on the side wall of the opening 141 of the mask 140 and/or the side wall of the recessed structure 130 in the subsequent etching process, an excessive heavy metal dopant may cause accumulation and thickening of a protection film in a deep hole etching protection area, increasing the risk of hole narrowing or even hole blocking. Thus, the present disclosure also includes controlling the total gas amount of the second passivating gas to be less than the total gas amount of the first passivating gas, so that the existing side wall protection effect can be maintained, and the etching progress may not be hindered by blocking the deep holes.

In one embodiment, the first passivating gas includes one or more of hydrogen bromide (HBr), hydrogen iodide (HI), bromine element (Br₂) and iodine element (I₂). Further, the heavy metal dopant in the second passivating gas refers to at least one of halides including a heavy metal, oxyhalides including a heavy metal, hydrides including a heavy metal, and hydroxylates including a heavy metal. In one embodiment, the gasified heavy metal dopant includes one or more of tungsten hexafluoride (WF₆), tungsten dichloride difluorooxide (WOF₂Cl₂), tungsten oxytetrachloride (WOCl₄), tungsten oxytetrafluoride (WOF₄), tungsten difluorodioxide (WO₂F₂), tungsten dichloride dioxide (WO₂Cl₂), molybdenum hexafluoride (MoF₆), molybdenum difluorodichloride (MoCl₂F₂), tin tetrahydride (SnH₄), rhenium hexafluoride (ReF₆), lead tetrahydride (PbH₄), nickel tetracarbonyl (Ni(CO)₄), germanium tetrahydride (GeH₄), germanium tetrafluoride (GeF₄), hydrogen arsine (AsH₃), arsenic chloride (AsCl₃), antimony boride (SbB₃), antimony chloride (SbCl₃), selenium hexafluoride (SeF₆), tin chloride (Se₂Cl₂), titanium tetrachloride (TiCl₄), and tantalum pentafluoride (TaF₅). As shown in FIG. 4, the first passivating gas and the second passivating gas cooperate with each other to form an etch protection area 170 on the side wall of the recessed structure 130 treated by the etching gas, and the subsequent deep etching by the etching gas of the stacked layers at this position is avoided, so that the etching rate of the etching protection area 170 is far lower than that of the lower stacked area, thus the side wall of the recessed structure 130 is not caused to produce a curved profile (especially the top side wall of the recessed structure 130), and a proper balance is maintained between the deposition rate and the etching rate of the etch protection area 170 to prevent blockage of deep holes, helping to ensure the flatness and collimation of the shape of the side wall of the recessed structure 130. It should be noted that, the component types of the first passivating gas and the second passivating gas are not limited to the types above, and according to actual process requirements and device conditions, the first passivating gas and the second passivating gas may also be other material gases, as long as they can cooperatively achieve the etching protection on the side wall of the recessed structure 130, which are not limited in the present disclosure.

Further, the etching gas includes one or more of CₓF_{y} and CₓH_{y}F_{z}, where x is greater than or equal to 1, y is greater than or equal to 1, z is greater than or equal to 1, and x, y, and z are all positive integers. Exemplarily, the etching gas is one or more of octafluoropropane (C₃F₈), octafluorocyclobutane (C₄F₈), perfluorobutadiene (C₄F₆), difluoromethane (CH₂F₂), methyl fluoride (CH₃F), trifluoromethane (CHF₃), carbon tetrafluoride (CF₄), octafluorocyclopentene (C₅F₈), and hexafluorobenzene (C₆F₆). Of course, the type of the etching gas is not limited thereto, and the present disclosure does not limit the type, as long as the stacked layers of the substrate 100 can be etched. For example, in other embodiments, the etching gas not only includes the etching chemical substances above, but also includes an oxidizer and/or an inert gas. In one embodiment, the oxidizer is one or more of oxygen (O₂), ozone (O₃), carbon monoxide (CO), carbonyl sulfide (COS) and nitrogen trifluoride (NF₃).

In one embodiment, when the used first passivating gas is HBr, the range of the flow rate thereof is 0-500 sccm; and/or, when the used second passivating gas is WF₆, the range of the flow rate thereof is 0-30 sccm; and/or when the used etching gas is CF₄, the range of the flow rate thereof is 0-1000 sccm, and/or the range of the flow rate of CHF₃ is 0-1000 sccm, the range of the flow rate of CH₂F₂ is 0-1000 sccm, and/or the range of the flow rate of O₂ is 0-200 sccm. Of course, the ranges of the flow rate of the first passivating gas/the second passivating gas and the etching gas are not limited to the above, and may also be other data ranges, which are not limited in the present disclosure. Exemplarily, the first passivating gas and the second passivating gas are gases with a higher melting boiling point, and the corresponding gas flow ranges thereof may decrease correspondingly.

In this embodiment, the etching treatment process of the substrate 100 is in a low temperature environment, so that the first passivating gas and the second passivating gas can form the passivation protection in the etching protection area 170 more easily. In one embodiment, the treatment temperature of the substrate 100 is less than or equal to −20° C. In this embodiment, the treatment temperature of the substrate 100 is −60° C., and the etching gas for etching the substrate 100 is a C1 gas containing F, i.e. a gas containing F of which the chemical formula includes a C. Under a low temperature condition, the C1 gas can still be maintained in a gas phase state, and an additional treatment device is not needed to perform a gasifying operation on the etching gas, thereby simplifying the process flow and reducing the requirements for the process device. Certainly, the etching gas is not limited to the above C1 light carbon substance, and may also be other heavy carbon substances in other embodiments. Correspondingly, a gasifying device may be provided to perform gasifying, so as to etch the stacked layers of the substrate 100. Further, in this embodiment, the first passivating gas of the passivating gas is HBr gas, the second passivating gas thereof is WF₆ gas, and the two passivating gases cooperate to form the etching protection area 170 on the side wall of the deep hole formed by the recessed structure 130 and the opening 141. In this embodiment, by means of the cooperation of HBr and WF₆, a polymerization by-product (such as WₓO_{y}F_{z}, SiₓO_{y}W_{z} and SiₓO_{y}Br_{z}) is generated on the side wall of the deep hole, so as to protect the position from subsequent etching by the etching tetragas, thereby ensuring the flatness and the collimation of the side wall position. In addition, when the temperature is lower than −20° C., with the decrease of the temperature, the process gas has a higher surface adsorption coefficient, the use of the Cl gas as an etching gas may show a higher etching rate (ER), a higher selectivity of etching for the mask 140 and the stacked layers (the selectivity of the mask 140), and a lower risk of closing the mask 140 or the recessed structure 130 at a relatively low power. On the other hand, as the main portion of the side wall protection layer is formed by the reaction of the first passivating gas and fluorocarbon groups generated by plasma treatment of the etching gas, and the heavy metal element contained by the second passivating gas after plasma treatment dopes the protection layer, the protection layer is more effective against the erosion of the scattered particles during the etching process, thereby enhancing the chemical stability of the protection layer. The flow rate of the second passivating gas is smaller than that of the first passivating gas, so as to prevent the openings 141 of the mask 140 or the opening of the recessed structure 130 from being closed prematurely due to excessive aggregation of the passivating gas in a low temperature state. By adjusting parameters such as the pulse frequency, pulse amplitude, phase difference and duty cycle of the first passivating gas and the second passivating gas, the total gas amount of the second passivating gas in the process is reduced, and the critical dimension of the top of the recessed structure 130 is precisely regulated.

Further, in this embodiment, during the treatment of the substrate 100, the etching gas is continuously introduced, that is, the etching reaction always exists. During the process that the passivating gas forms the etching protection area on the side wall of the recessed structure 130, the etching gas also etches a part of the deposited polymer, so as to avoid excessive aggregation of the product of the passivating gas, and avoid premature closing of the opening 141 of the mask 140 and the recessed structure 130. Due to the steric hindrance effect of the gas diffusion, the amount of the passivating gas and the etching gas contacted by the top area of the recessed structure 130 is the largest, and the continuous introduction of the etching gas may prevent premature closing of the opening 141 of the mask 140 and the top opening of the recessed structure 130 due to excessive aggregation of the polymer generated by the passivating gas. Further, the etching profile of the recessed structure 130 of the substrate 100 has a good continuity, which helps to ensure smoothness and collimation of the side wall of the recessed structure 130. At the same time, in this process, an etching gas-related power module is always in an on state, the adjustment of the process parameters (such as the radio frequency power, gas type, and gas pressure) in the process is very convenient, and the radio frequency can reach a matching state quickly, which helps to improve the process performance.

In this embodiment, the two passivating gases are introduced in a pulsed manner, i.e. HBr and WF₆ enter the treatment chamber in a pulsed manner, respectively. In this embodiment, the total content of the passivating gas is far less than the total content of the etching gas, so that the sidewall of the recessed structure 130 can be protected by using a trace amount of passivating gas while the etching efficiency is ensured.

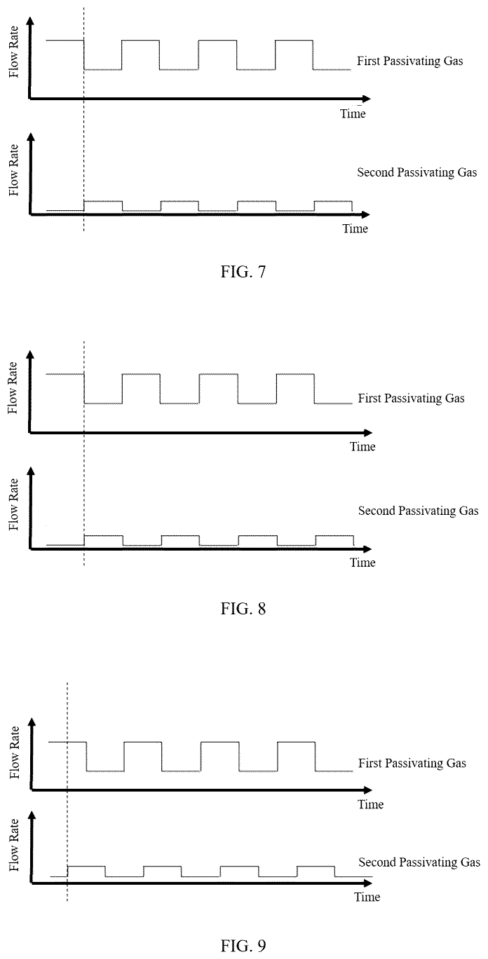

When the pulsed gas-introduction manner is used, the total gas amount of any one of the etching gas, the first passivating gas or the second passivating gas satisfies the following formula:
total gas amount=time*duty cycle*flow rate of gas, where
the time is usually a period of a certain gas, the total gas amount of the passivating gas has a direct influence on the thickness of the side wall protection film, and the relative total gas amounts of the first passivating gas and the second passivating gas in the treatment chamber within the same time can be influenced by adjusting the phase difference, the period, the duty cycle and the flow rate of the two types of passivating gases. In one embodiment, when the time is selected as a unit period of the second passivating gas, as shown in FIG. 6, the amount of the first passivating gas and the second passivating gas are far less than that of the etching gas. In some embodiments, the total gas amount of the first passivating gas of the passivating gas is 1-10% of the total gas amount of the etching gas, and the total gas amount of the second passivating gas is 0.1-1% of the total gas amount of the etching gas. Of course, the ratio percentages of the flow rates of the first passivating gas and the second passivating gas to the etching gas are not limited to the above, and may also be in other numerical ranges according to actual requirements of the process.

In this embodiment, a flow rate ratio of the second passivating gas in the treatment chamber is smaller than that of the first passivating gas. In one embodiment, the total gas amount of the second passivating gas in the treatment chamber is 1-10% of the total gas amount of the first passivating gas, compared with the first passivating gas, the second passivating gas is easier to deposit on the side wall, and by the ratio of the total gas amount, the opening degree of the recessed structure 130 meeting the requirements can be obtained, so that the passivation speed and the etching speed of the etching protection area 170 are balanced, not only achieving the effect of protection, but also not closing the opening of the recessed structure 130, and further conveniently controlling the accuracy of transmission of a gas with a small flow rate and reducing the difficulty of control. The pulse periods of the first passivating gas and the second passivating gas may or may not be synchronized, that is, the pulse phase difference between the first passivating gas and the second passivating gas is within 0-1 periods. The two passivating gases may adopt an on-off-on-off pulse mode, and may also adopt a pulse mode of high flow rate-low flow rate-high flow rate-low flow rate. In order to achieve the component contents of two types of passivating gases within a period of time as stated above, In one embodiment, the pulse frequency of the first passivating gas is greater than the pulse frequency of the second passivating gas; and/or the duration of single-pulsed introduction of the first passivating gas is longer than the duration of single-pulsed introduction of the second passivating gas; and/or the pulse intensity, i.e. the pulse flow rate, of the first passivating gas is higher than the pulse intensity of the second passivating gas per unit time. In some embodiments, when the first passivating gas is HBr and the second passivating gas is WF₆, the duty cycle of the HBr introduced in pulses into the treatment chamber is n times the duty cycle of the WF₆ gas therein, where n is a positive integer, for example, n=2. In the same time period, for example, taking a cycle period of the second passivating gas as an example, when the first passivating gas is in a low flow rate interval, the second passivating gas is in a high flow rate interval, and subsequently, when the second passivating gas is in a low flow rate interval, the first passivating gas passes through two high flow rate intervals and one low flow rate interval. During the treatment of the substrate 100, the etching process of the etching gas and the side wall protection process of the passivating gas exist at the same time, so as to avoid excessive etching of the etching gas.

Of course, the process parameters of the first passivating gas and the second passivating gas may not be described above, which are not limited in the present disclosure. For example, in another embodiment, the durations of single-pulsed introduction of the first passivating gas and the second passivating gas are the same, and the pulse amplitude of the first passivating gas is greater than the pulse amplitude of the second passivating gas (for example, the pulse amplitude of the second passivating gas is 1-10% of the pulse amplitude of the first passivating gas). Further, the proportional relationship between the flow rates of the first passivating gas and the second passivating gas is not limited to that described above. For example, in other embodiments, the ratios of the flow rates of the first passivating gas and the second passivating gas are the same, so as to precisely control the passivating gas introduced into the treatment chamber, and to adjust the different component contents of the two gases by controlling different introduction times.

In the following, the factors affecting the ratio of the two passivating gases in the treatment chamber described above are adjusted by means of specific embodiments, so as to achieve the purpose of the second passivating gas having a lower component content than the first passivating gas.

### Embodiment I

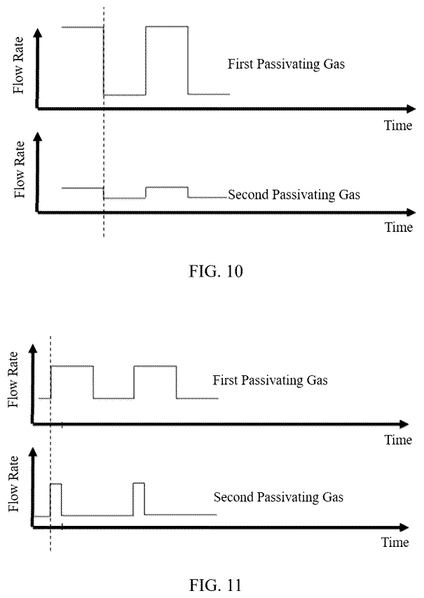

As shown in FIG. 7, in this embodiment, the maximum gas flow rate of the first passivating gas is greater than the maximum gas flow rate of the second passivating gas, the pulse period length of the first passivating gas is half of the pulse period length of the second passivating gas, the duty cycle of the first passivating gas is twice that of the second passivating gas, and in this case, the time is selected to be a time in the period of the second passivating gas, and then the total amount of the second passivating gas in the treatment chamber is substantially less than the total amount of the first passivating gas therein.

### Embodiment II

As shown in FIG. 8, the difference from the described embodiment lies in that the period lengths and the duty cycles of the first passivating gas and the second passivating gas are the same, the two types of passivating gas are introduced alternately with the maximum flow rate, i.e. when the first passivating gas is introduced at the maximum pulse flow rate, the second passivating gas is introduced at the minimum pulse flow rate, and when the first passivating gas is introduced at the minimum pulse flow rate, the second passivating gas is introduced at the maximum pulse flow rate, where the minimum pulse flow rate can be zero. Although the period length and the duty cycle of the first passivating gas are the same as the period length and the duty cycle of the second passivating gas, as the gas flow rate of the first passivating gas is higher than that of the second passivating gas, the total amount of the first passivating gas is always higher than the total amount of the second passivating gas during the process.

### Embodiment III

As shown in FIG. 9, the difference from the described embodiment lies in that a phase difference exists between the singled-pulse introduction and cut-off of the first passivating gas and the second passivating gas, that is, in the same period, there is a time period in which the two passivating gases are introduced at the same time at the maximum pulse flow rate, and there is also a time period in which two passivating gases are introduced at the same time with the minimum pulse flow rate, the first passivating gas is introduced first so as to be diffused first in the reaction chamber and the recessed structure 130, and then the second passivating gas is introduced to cooperate with the first passivating gas, so as to protect the side wall of the recessed structure 130.

### Embodiment IV

As shown in FIG. 10, the difference from the described embodiment lies in that the first passivating gas and the second passivating gas have the same pulse frequency (period) and duty cycle, the total input amount of the two types of gases depends on the gas flow rate, and the maximum flow rate of the second passivating gas should be maintained at 0.01-10% of the maximum flow rate of the first passivating gas, so as to achieve the balance between protection of the side wall and avoidance of hole blocking.

### Embodiment V

As shown in FIG. 11, the difference from the described embodiment lies in that the first passivating gas and the second passivating gas have the same pulse frequency (period) and maximum pulse flow rate, the total input amount of the two types of gases is determined by the pulse duty cycle, and the pulse duty cycle of the second passivating gas needs to be 0.01-10% of that of the first passivating gas, so as to achieve the good balance between protection of the side wall and avoidance of hole blocking.

Further, in this embodiment, the etching gas is introduced into the reaction chamber at a constant flow rate, so as to achieve uniform etching of the stacked layers of the substrate 100. Of course, the delivery manner of the etching gas is not limited to the described manner, and the etching gas may also be delivered in other manners. For example, in other embodiments, in order to balance the etching effect of the etching gas and the protection effect of the side wall of the passivating gases, the etching gas is introduced in a pulsed manner, and a unit period thereof includes a low pulse intensity stage and a high pulse intensity stage, that is, the etching gas is not introduced into the reaction chamber at a high intensity all the time, thereby avoiding excessive etching on the side wall of the recessed structure 130. In one embodiment, when the etching gas is inputted in the manner of a low pulse intensity stage, the pulse input amount of the passivating gases is relatively small, and when the etching gas is inputted in the manner of a high pulse intensity stage, the pulse input amount of the passivating gases is relatively large. Preferably, within a unit time, the start time of the high pulse intensity stage of the etching gas is the same as the pulse start time of the first passivating gas, that is, the content growth process of the etching gas in the treatment chamber is accompanied by the content growth process of the first passivating gas of the passivating gas, and the main process of the etching process and the main process of the side wall protection exist at the same time, which not only implements the continuous etching of the stacked layers of the substrate 100, but also avoid excessive etching of the side wall of the recessed structure 130 caused by the excessive etching gas in the reaction chamber, thereby achieving dynamic balance between the etching process and the side wall protection process.

It should be noted that, the etching method for a substrate 100 according to the present disclosure is not only applicable to the low-temperature treatment process above, but also applicable to the substrate treatment process at a normal temperature (about 25° C.). Exemplarily, in another embodiment, the treatment temperature of the substrate 100 is different from that in this embodiment, and in this embodiment, the substrate 100 is subjected to the process at the normal temperature (about 25° C.).

Unlike this embodiment, in that embodiment, the etching gas may contain a C4 gas in addition to the C1 gas. When the C1 gas is used as the etching gas, compared with the low-temperature state, the adsorptive property of the C1 gas on the material in a normal temperature state is slightly reduced, and thus the etching gas does not excessively etch the recessed structure 130 of the substrate 100. On the other hand, when the C4 gas is used as the etching gas, compared with the C1 gas, the C4 gas has a significantly improved adsorptive property, which helps to control the etching process and the side wall protection process. Alternatively, in the normal temperature state, when the C4 gas is used as the etching gas, the aspect ratio of the recessed structure 130 obtained thereby is greater than or equal to 40.

In summary, in the etching method for a substrate 100 and a semiconductor device thereof provided by the present disclosure, the method including the following operations: transferring a substrate 100 into a treatment chamber; introducing an etching gas and a passivating gas into the treatment chamber to perform treatment on the substrate 100, the etching gas including one or more fluorinated gases containing carbon so as to perform etching to form a recessed structure 130 on the substrate 100, the passivating gas including a first passivating gas and a second passivating gas and being used for forming an etching protection area 170 on a side wall of the recessed structure 130, the first passivating gas including a halogen element and/or a hydrogen halide gas, and the second passivating gas including a gasified heavy metal dopant. During treatment of the passivating gas, in the treatment chamber, the total gas amount of the second passivating gas is less than the total gas amount of the first passivating gas. In the method, a fluorinated gas containing carbon is used as the etching gas, the effective fast etching on a substrate 100 can be implemented by means of free radicals containing fluorine, and a halogen element gas, a hydrogen halide gas or a combination thereof is used as a first passivating gas and a heavy metal dopant gas is used as a second passivating gas, which are used together as a passivating gas combination, so as to achieve a suitable side wall deposition speed and degree for performing etching to form the recessed structure 130. In the method, an etching protection area 170 is formed on a side wall of the recessed structure 130 by means of cooperation of free radicals containing carbon and a halogen element and/or a hydrogen halide gas and a heavy metal dopant, so as to avoid differential expansion of the side wall of the recessed structure 130 when the substrate 100 is etched by the etching gas, thereby further ensuring the flatness of the side wall of the recessed structure 130, providing a good basis for the subsequent substrate 100 fabrication, and helping to improve the yield of substrate 100 fabrication. In addition, in the method, the total gas amount of the second passivating gas is further controlled to be less than the total gas amount of the first passivating gas, so as to protect the side wall without blocking a deep hole finally due to its own accumulation, thereby further ensuring the normal progress of treatment the recessed structure 130.

Although the contents of the present disclosure are described in detail with reference to the preferred embodiments above, it should be understood that the description above should not be taken as limiting. After reading the foregoing disclosure, many modifications and alternatives to the present disclosure by those skilled in the art will be apparent. Therefore, the scope of protection of the present disclosure shall be defined by the appended claims.

1. A method of etching a substrate, comprising:
transferring the substrate into a treatment chamber;
introducing an etching gas and a passivating gas into the treatment chamber to perform a treatment on the substrate, the etching gas comprising one or more fluorinated gases containing carbon, so as to perform etching to form a recessed structure on the substrate, wherein
the passivating gas comprises a first passivating gas and a second passivating gas, and is used for forming an etching protection area on a side wall of the recessed structure, the first passivating gas comprises at least one of a halogen element or a hydrogen halide gas, and the second passivating gas comprises a gasified heavy metal dopant; and
during a treatment of the passivating gas, a total gas amount of the second passivating gas in the treatment chamber is less than a total gas amount of the first passivating gas.

2. The method according to claim 1, wherein,
the first passivating gas comprises one or more of HBr, HI, Br₂, or I₂.

3. The method according to claim 1, wherein,
the gasified heavy metal dopant comprises one or more of WF₆, WOF₂Cl₂, WOCl₄, WOF₄, WO₂F₂, WO₂Cl₂, MoF₆, MoCl₂F₂, SnH₄, ReF₆, PbH₄, Ni(CO)₄, GeH₄, GeF₄, AsH₃, AsCl₃, SbB₃, SbCl₃, SeF₆, Se₂Cl₂, TiCl₄, or TaF₅.

4. The method according to claim 1, wherein,
the etching gas comprises one or more of CₓF_{y} or CₓH_{y}F_{z}, wherein x is greater than or equal to 1, y is greater than or equal to 1, z is greater than or equal to 1, and x, y, and z are all positive integers.

5. The method according to claim 1, wherein,
during the treatment, the etching gas is continuously introduced;
and/or the passivating gas is introduced in a pulsed manner.

6. The method according to claim 1, wherein,
the first passivating gas and the second passivating gas are introduced in pulses of the first passivating gas and pulses of the second passivating gas respectively, and a phase difference between the pulses of the first passivating gas and the pulses of the second passivating gas is within 0-1 periods.

7. The method according to claim 6, wherein,
a pulse frequency of the first passivating gas is greater than a pulse frequency of the second passivating gas;
and/or a duration of single-pulsed introduction of the first passivating gas is longer than a duration of single-pulsed introduction of the second passivating gas;
and/or a pulse intensity of the first passivating gas is higher than a pulse intensity of the second passivating gas per unit time.

8. The method according to claim 6, wherein,
a pulse duty cycle of the second passivating gas is less than or equal to a pulse duty cycle of the first passivating gas.

9. The method according to claim 6, wherein,
a pulse period of the second passivating gas is n times of a pulse period of the first passivating gas, n being a positive integer.

10. The method according to claim 6, wherein,
a pulse amplitude of the second passivating gas is 1-10% of a pulse amplitude of the first passivating gas.

11. The method according to claim 6, wherein,
the etching gas is introduced in pulses, and a unit period thereof comprises a low pulse intensity stage and a high pulse intensity stage.

12. The method according to claim 11, wherein,
within a unit time, a start time of the high pulse intensity stage of the etching gas is same as a pulse start time of the first passivating gas.

13. The method according to claim 1, wherein,
in a period of the second passivating gas:
the total gas amount of the second passivating gas in the treatment chamber is 1-10% of the total gas amount of the first passivating gas;
and/or the total gas amount of the first passivating gas is 1%-10% of a total gas amount of the etching gas;
and/or the total gas amount of the second passivating gas is 0.1-1% of the total gas amount of the etching gas.

14. The method according to claim 1, wherein,
a range of a flow rate of the first passivating gas is 0-500 sccm;
and/or a range of a flow rate of the second passivating gas is 0-30 sccm;
and/or a range of a flow rate of the etching gas is 0-1000 sccm.

15. The method according to claim 1, wherein,
a treatment temperature of the substrate is less than or equal to −20° C.

16. The method according to claim 1, wherein,
a treatment temperature of the substrate is −60° C.

17. The method according to claim 1, wherein,
a treatment temperature of the substrate is less than or equal to 25° C.

18. The method according to claim 1, wherein,
an aspect ratio of the recessed structure is greater than or equal to 40.

19. The method according to claim 1, wherein,
an aspect ratio of the recessed structure is greater than or equal to 50.

20. A method of etching a substrate, comprising:
transferring the substrate into a treatment chamber; and
introducing an etching gas and a passivating gas into the treatment chamber to perform a treatment on the substrate so as to generate a recessed structure, wherein a treatment temperature of the substrate is less than or equal to −20° C., the etching gas comprises a C1 gas containing F for etching the substrate, and the passivating gas comprises a first passivating gas including a HBr gas and a second passivating gas including a WF₆ gas, so as to form an etch protection area on a sidewall of the recessed structure.

21. The method according to claim 20, wherein,
an aspect ratio of the recessed structure is greater than or equal to 50.

22. The method according to claim 20, wherein,
during the treatment, the etching gas is continuously introduced.

23. The method according to claim 20, wherein,
the passivating gas is introduced in a pulsed manner, wherein a duty cycle of the HBr gas is twice of a duty cycle of the WF₆ gas.

24. A semiconductor device, comprising:
a substrate, wherein
stacked layers of different materials are alternately provided on the substrate, and the stacked layers comprise silicon nitride layers and silicon oxide layers; and
a recessed structure manufactured by using the method according to claim 1 is provided in the stacked layers.
